(19) United States
(12) Patent Application Publication
(10) Pub. No.: US 2023/0142695 A1
(43) Pub. Date: May 11, 2023

(54) SEMICONDUCTOR DEVICE AND MANUFACTURING METHOD THEREFOR

(71) Applicant: FUJI ELECTRIC CO., LTD., Kawasaki-shi (JP)

(72) Inventors: Yuichiro HINATA, Matsumoto-city (JP); Naoyuki KANAI, Matsumoto-city (JP); Takashi SAITO, Matsumoto-city (JP)

(73) Assignee: FUJI ELECTRIC CO., LTD., Kawasaki-shi (JP)

(21) Appl. No.: 17/954,191

(22) Filed: Sep. 27, 2022

(30) Foreign Application Priority Data
Nov. 11, 2021 (JP) 2021-184338

(51) Int. Cl. H01L 23/31; H01L 23/00; H01L 21/56; H01L 23/498

(52) U.S. Cl. CPC H01L 23/3142; H01L 24/83; H01L 23/3135; H01L 24/32; H01L 21/563; H01L 23/49894; H01L 23/49822; H01L 24/75; H01L 2224/32225; H01L 2224/3201; H01L 2224/32058; H01L 2224/32059; H01L 2224/26175; H01L 2224/83203; H01L 2224/75312; H01L 2224/75305; H01L 2224/8384

(57) ABSTRACT

A semiconductor device includes an insulated circuit board having a conductive pattern layer, a sintered member disposed on the conductive pattern layer, a semiconductor chip placed on the sintered member, and a coating material covering the semiconductor chip. The sintered member has, on a surface thereof opposite to the conductive pattern layer, a frame shaping the outer edge of a recess. The semiconductor chip is mounted in the recess such that its top face is located closer to the conductive pattern layer than a top end of the frame.

### CROSS-REFERENCE TO RELATED APPLICATION

This application is based upon and claims the benefit of priority of the prior Japanese Patent Application No. 2021-184338, filed on Nov. 11, 2021, the entire contents of which are incorporated herein by reference.

### BACKGROUND OF THE INVENTION

### 1. Field of the Invention

The embodiments discussed herein relate to a semiconductor device and manufacturing method therefor.

### 2. Background of the Related Art

As for semiconductor devices, there are known techniques for using resin to cover a semiconductor chip or element mounted on a predetermined substrate.

For example, there is a known technique for providing, on a circuit board where an integrated circuit (IC) chip is mounted, a dam resin to enclose the periphery of the IC chip with no gap and filling the inside of the dam resin with a sealant resin to seal the IC chip (Japanese Laid-open Patent Publication No. H09-69591).

There is another known technique for mounting a semiconductor chip in a recess created in a die pad of a lead frame, coating the surface of the semiconductor chip by filling the recess with a junction coating resin, and forming a resin package around the semiconductor chip (Japanese Laid-open Patent Publication No. H07-38027).

There is yet another known technique for forming, on a retaining plate where a semiconductor element is mounted, a ring-shaped frame made of an adhesive or solder to enclose the semiconductor element and providing, in a receptacle portion formed by the frame, a protecting resin that covers the semiconductor element (Japanese Laid-open Patent Publication No. H11-135686).

Yet another known technique is to arrange, on a circuit board with a semiconductor element mounted thereon, adjacent to the periphery of the semiconductor element, an outflow preventing member made up of a band-like copper pattern and a gold-plated layer having low wettability to a sealant resin. Due to the low wettability, the gold-plated layer prevents the sealant resin from flowing out of a sealing region after the sealant resin is injected thereto (Japanese Laid-open Patent Publication No. 2004-214255).

Relating to a semiconductor device where, on a lead frame, a semiconductor chip is mounted via solder while a circuit board is mounted via a resin adhesive and their surrounds are sealed with a mold resin, yet another known technique is to coat the top face and peripheral region of the semiconductor chip with a protecting resin in order to increase adhesion with the mold resin and relieve thermal stress (Japanese Laid-open Patent Publication No. 2005-93635). In addition, in such a semiconductor device, yet another known technique is to provide the lead frame with a convex striated portion (dam portion) along the boundary between an area for mounting the semiconductor chip and an area for mounting the circuit board in order to prevent the protecting resin applied to coat the top face and the peripheral region of the semiconductor chip from flowing into the circuit board mounting area (Japanese Laid-open Patent Publication No. 2005-93635).

Relating to a semiconductor device, yet another known technique is to mount a multilayer semiconductor chip on a circuit board; perform molding treatment to apply a dam material composition around the multilayer semiconductor chip; cause an underfill material composition to infiltrate, from between the multilayer semiconductor chip and the dam material composition, the gap between the multilayer semiconductor chip and the circuit board; and allow the dam material composition and the underfill material composition to cure (Japanese Laid-open Patent Publication No. 2011-14885).

There are also known techniques for flip-chip bonding a semiconductor chip on a circuit board via resin, such as an anisotropic conductive film, and for pressurizing the resin that flows out of the semiconductor chip due to pressure applied to the semiconductor chip at the time of flip-chip bonding, to thereby squeeze out voids within the resin and further improve adhesion between the semiconductor chip and the circuit board (Japanese Laid-open Patent Publication No. 2001-127105). It is suggested to use a pressurizing jig for bonding in applying pressure to the semiconductor chip and the resin. The pressurizing jig is provided with a recess having, on a surface of contact with the semiconductor chip, an opening with substantially the same shape as the outer shape of the semiconductor chip; having a depth less than the height from the top face of the circuit board to the top face of the semiconductor chip after the semiconductor chip is connected to the circuit board; and mating with the semiconductor chip directly or via a sheet member at the time of pressurization (Japanese Laid-open Patent Publication No. 2001-127105).

There is one known form of semiconductor device in which a semiconductor chip is mounted, via a sintered member, on an insulated circuit board having a conductive pattern layer. The semiconductor chip on the insulated circuit board is sealed with a sealant of, for example, epoxy resin. In such a semiconductor device, stress occurs internally due to temperature loads caused by heat generation during operation and subsequent cooling. At that time, if the stress exceeds the adhesion force of the sealant due to the difference in the coefficient of thermal expansion between the semiconductor chip and the sealant enclosing the semiconductor chip, the sealant may be debonded from the semiconductor chip. Debonding of the sealant from the semiconductor chip may lead to reduced reliability and poor insulation performance of the semiconductor chip and a semiconductor device provided with the semiconductor chip.

In some cases, a coating material for increasing adhesion and relieving stress is interposed between the semiconductor chip and the sealant in order to prevent the sealant from separating from the semiconductor chip. A known way to provide the coating material is to place a flowable coating material on the semiconductor chip and spread the coating material all over the surface of the semiconductor chip and the like. However, if the viscosity of the coating material is too high, the coating material is not sufficiently distributed over the surface of the semiconductor chip and the like. On the other hand, if the viscosity is too low, the coating material may run off, which may cause the semiconductor chip to be partially (e.g., its corner portion) exposed or not to be covered with the coating material of sufficient thickness. In turn, such poor formation of the coating material may cause reduced contact between the semiconductor chip and the sealant or decrease the adhesion enhancing effect and the stress relaxation effect. These defects may result in debonding of the sealant due to stress induced by temperature loads, which possibly leads to reduced reliability and poor insulation performance of the semiconductor chip and the semiconductor device, as described above.

### SUMMARY OF THE INVENTION

According to an aspect, there is provided a semiconductor device including an insulated circuit board including a conductive pattern layer; a sintered member disposed on the conductive pattern layer, the sinter member having a frame formed on a surface thereof opposite to the conductive pattern layer, to thereby form a recess on the surface, the frame shaping an outer edge of the recess; a semiconductor chip having a top face, a bottom face opposite to the top face, and a lateral face, the semiconductor chip being mounted in the recess with the bottom face opposing the recess, the top face being located closer to the conductive pattern layer than a top end of the frame; and a coating material covering the semiconductor chip mounted in the recess.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIGS. 1A and 1B illustrate an example of a semiconductor device according to a first embodiment;

FIGS. 2A and 2B are a first part of drawings illustrating an example of a semiconductor chip bonding process according to the first embodiment;

FIG. 3 is a second part of the drawings illustrating the example of the semiconductor chip bonding process according to the first embodiment;

FIGS. 4A and 4B illustrate an example of a coating process according to the first embodiment;

FIGS. 5A and 5B illustrate an example of a coating process according to a different form;

FIG. 6 illustrates an example of a sealing process according to the first embodiment;

FIG. 7 illustrates another example of the semiconductor device according to the first embodiment;

FIGS. 8A and 8B illustrate a first modification of the semiconductor device according to the first embodiment;

FIGS. 9A and 9B illustrate a second modification of the semiconductor device according to the first embodiment;

FIGS. 10A and 10B illustrate an example of a semiconductor device according to a second embodiment;

FIGS. 11A and 11B illustrate an example of a jig used to form the semiconductor device according to the second embodiment;

FIGS. 12A and 12B are a first part of drawings illustrating an example of a semiconductor chip bonding process according to the second embodiment;

FIGS. 13A and 13B are a second part of the drawings illustrating the example of the semiconductor chip bonding process according to the second embodiment;

FIGS. 14A and 14B illustrate an example of a coating process according to the second embodiment;

FIG. 15 illustrates an example of a sealing process according to the second embodiment;

FIGS. 16A to 16D illustrate modifications of the jig according to the second embodiment; and

FIG. 17 illustrates an example of a semiconductor device manufacturing method according to a third embodiment.

### DETAILED DESCRIPTION OF THE INVENTION

### (a) First Embodiment

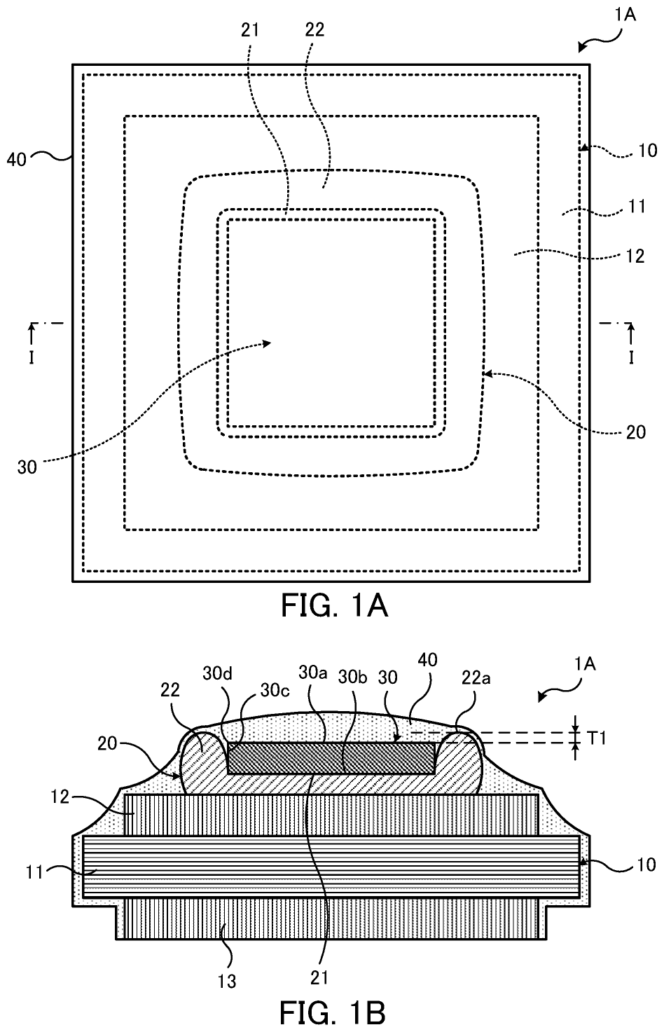

FIGS. 1A and 1B illustrate an example of a semiconductor device according to a first embodiment. FIG. 1A is a schematic plan view with relevant parts of the semiconductor device, and FIG. 1B is a schematic cross-sectional view with relevant parts of the semiconductor device. FIG. 1B is a cross-sectional view of the semiconductor device along I-I of FIG. 1A.

A semiconductor device 1A of FIGS. 1A and 1B includes an insulated circuit board 10, a sintered member 20, a semiconductor chip 30, and a coating material 40.

The insulated circuit board 10 includes an insulating substrate 11 and conductive pattern layers 12 and 13, as illustrated in FIGS. 1A and 1B. Each of the conductive pattern layers 12 and 13 is arranged in a predetermined shape on one of both main surfaces of the insulating substrate 11. The insulating substrate 11 is made of a material with excellent electrical insulation and thermal conductivity. For example, a substrate made of alumina, a complex ceramic containing alumina as a main component, aluminum nitride, silicon nitride, or the like is used as the insulating substrate 11. The conductive pattern layers 12 and 13 are made of a material with excellent electrical conductivity and workability. For example, the conductive pattern layers 12 and 13 are made of a metal, such as copper or aluminum. For the conductive pattern layers 12 and 13, copper, aluminum, or the like subjected to nickel plating may be used for the purpose of rust prevention. The conductive pattern layers 12 and 13 are fabricated on the insulating substrate 11, for example, by direct copper bonding or active metal brazing.

The sintered member 20 is disposed on the conductive pattern layer 12 of the insulated circuit board 10, as illustrated in FIGS. 1A and 1B. The sintered member 20 is an example of material electrically and mechanically connecting the conductive pattern layer 12 of the insulated circuit board 10 and the semiconductor chip 30 placed on the sintered member 20. The sintered member 20 has a structure obtained by, for example, pressurizing and heating a paste-like material containing nano-sized or micro-sized conductive particles, to thereby sinter the conductive particles together. The conductive particles of the sintered member 20 are made of, for example, a metal such as gold, silver, or copper, or a material based on such a metal. Note however that the material of the conductive particles is not limited to these.

The semiconductor chip 30 is arranged on the sintered member 20 disposed on the conductive pattern layer 12 of the insulated circuit board 10, as illustrated in FIGS. 1A and 1B. The semiconductor chip 30 includes a top face 30a; a bottom face 30b located on the opposite side of the semiconductor chip 30 from the top face 30a; a lateral face 30c lying between the top face 30a and the bottom face 30b; and a corner portion 30d lying between the top face 30a and the lateral face 30c. The semiconductor chip 30 is embedded in the sintered member 20 such that, amongst the top face 30a, the bottom face 30b, the lateral face 30c, and the corner portion 30d, at least the bottom face 30b is in contact with the sintered member 20 and at least the top face 30a is exposed from the sintered member 20. Note that the positional relationship between the semiconductor chip 30 and the sintered member 20 is described later.

As the semiconductor chip 30, a semiconductor element, such as an insulated gate bipolar transistor (IGBT) or a metal oxide semiconductor field effect transistor (MOSFET), is used. Alternatively, a different type of semiconductor element, such as a junction field effect transistor (JFET) or a high electron mobility transistor (HEMT) may be used for the semiconductor chip 30. In the case of using an IGBT, a MOSFET or the like, a diode element, such as a free wheeling diode (FWD) or a Schottky barrier diode (SBD), may be mounted together with or connected to the semiconductor element. Various types of devices, such as a silicon device, a silicon carbide device, or a gallium nitride device may be used as the semiconductor chip 30.

In addition to the semiconductor chip 30, other semiconductor chips akin to or different from the type of the semiconductor chip 30, or various types of electronic components and the like, may be arranged on the insulated circuit board 10. The semiconductor chip 30 mounted on the insulated circuit board 10 may be connected to different conductive pattern layers, semiconductor chips and the like provided on the insulated circuit board 10 by means of conductive members, such as wires and clips.

The coating material 40 is placed to cover the semiconductor chip 30, as illustrated in FIGS. 1A and 1B. The coating material 40 is laid to cover, for example, the sintered member 20 and the insulated circuit board 10 in addition to the semiconductor chip 30. An organic material is used for the coating material 40. The material used as the coating material 40 provides excellent adhesion to a sealant, such as an epoxy resin composition, used for sealing the semiconductor chip 30 and has the effect of relieving stress exerted on the semiconductor chip 30 and the sealant. For example, the coating material 40 is made of, but not limited to, a resin material, such as a polyimide resin, a polyether amide resin, a polyetherimide resin, or a polyamide-imide resin.

As for the insulated circuit board 10, terminal parts and the like that are connected to the semiconductor chip 30 and the like may also be provided thereon. The insulated circuit board 10 has the conductive pattern layer 13, which is located on the opposite side from the conductive pattern layer 12 where the semiconductor chip 30 is mounted via the sintered member 20. The conductive pattern layer 13 may be bonded to a different substrate, such as a heat dissipation base or a lead frame, via a different bonding member, such as a solder member or a sintered member.

Next described is a positional relationship between the semiconductor chip 30 and the sintered member 20 of the semiconductor device 1A having the above-described configuration.

The semiconductor chip 30 is embedded in the sintered member 20 laid on the conductive pattern layer 12 of the insulated circuit board 10 in such a manner that the top face 30a thereof is exposed. The sintered member 20 has, on a surface thereof opposite to the conductive pattern layer 12, a recess 21 and a frame 22 shaping an outer edge of the recess 21. The recess 21 of the sintered member 20 is formed, when the semiconductor chip 30 is pushed into the sintered member 20 on the conductive pattern layer 12, by applying pressure to the sintered member 20 with the bottom face 30b of the semiconductor chip 30. The frame 22 of the sintered member 20 is formed of the sintered member 20 extruded around the semiconductor chip 30 when the recess 21 is formed. In this manner, the semiconductor chip 30 is embedded in the recess 21 of the sintered member 20, with the top face 30a thereof exposed, and the periphery of the semiconductor chip 30 is surrounded by the frame 22 of the sintered member 20.

At that time, the semiconductor chip 30 is embedded in the recess 21 of the sintered member 20 such that the top face 30a is located closer to the conductive pattern layer 12 than a top end 22a of the frame 22 of the sintered member 20. That is, in embedding the semiconductor chip 30 in the sintering member 20, the semiconductor chip 30 is positioned so that the top face 30a and the top end 22a of the frame 22 of the sintered member 20 have this positional relationship. FIG. 1B illustrates a case where the semiconductor chip 30 is embedded in the sintered member 20 such that the top face 30a of the semiconductor chip 30 is located lower and closer to the conductive pattern layer 12, by a height difference T1, than the top end 22a of the frame 22 of the sintered member 20.

The coating material 40 is arranged on the semiconductor chip 30 thus positioned on the sintered member 20. For example, the coating material 40 having fluidity is placed on the top face 30a side of the semiconductor chip 30 and then flows to spread. In this manner, the semiconductor chip 30 is covered by the coating material 40. The coating material 40 covers, not only the semiconductor chip 30, but also the sintered member 20 and the insulated circuit board 10, as illustrated in FIGS. 1A and 1B. The coating material 40 covering the semiconductor chip 30 and the like is then cured.

In the semiconductor device 1A, the top face 30a of the semiconductor chip 30 is located closer to the conductive pattern layer 12 than the top end 22a of the frame 22 of the sintered member 20. Therefore, the coating material 40 laid on the semiconductor chip 30 remains inside the frame 22 (the recess 21) of the sintered member 20 and is thus prevented from flowing to the outside of the frame 22. That is, the frame 22 of the sintered member 20 functions as a dam for the coating material 40. Thus, in the semiconductor device 1A, the coating material 40 stays inside the frame 22 of the sintered member 20, which prevents the semiconductor chip 30 (including the top face 30a, the lateral face 30c, and the corner portion 30d lying between the top face 30a and the lateral face 30c) from being exposed from the coating material 40.

As a result, when the semiconductor chip 30 and the like are sealed with a sealant after the coating material 40 is formed, the semiconductor chip 30 and the sealant do not come into direct contact with each other. The coating material 40 interposed between the semiconductor chip 30 and the sealant enhances their adhesion to each other and relieves stress exerted on them. This prevents separation of the sealant due to stress caused by temperature loads associated with heat generation during operation and subsequent cooling and the difference in the coefficient of thermal expansion between the semiconductor chip 30 and the sealant. By preventing the sealant from being debonded, it is possible to avoid undermining the credibility of the semiconductor chip 30 and the semiconductor device 1A provided with the semiconductor chip 30 and reduce the loss of their insulation performance.

A method of formation of the semiconductor device 1A having the above-described configuration is described next in greater detail.

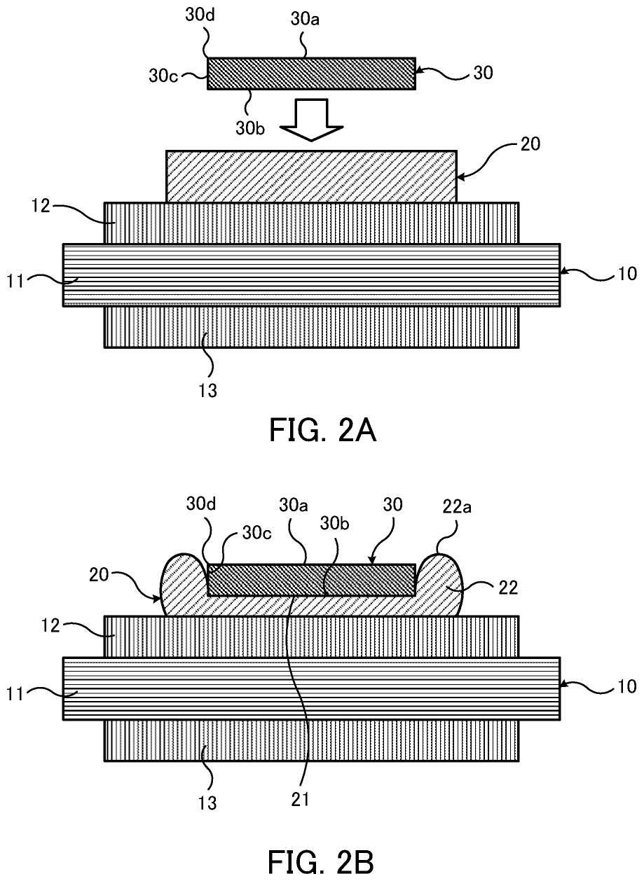

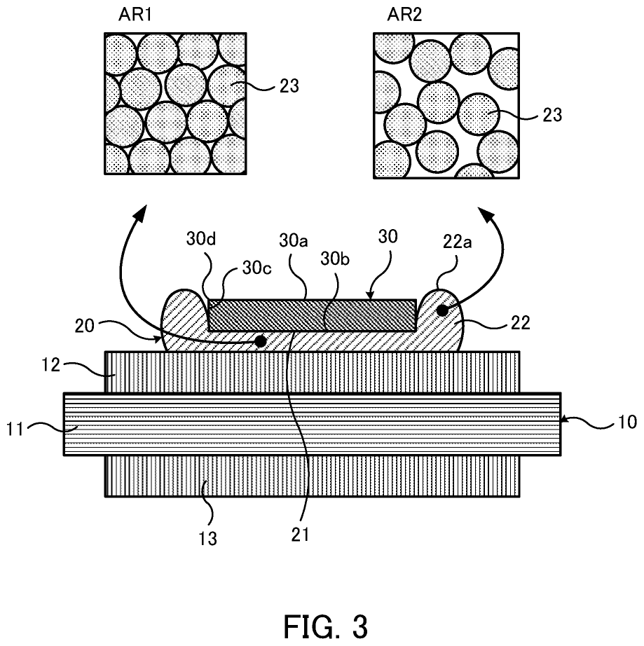

FIGS. 2A, 2B, and 3 illustrate an example of a semiconductor chip bonding process according to the first embodiment. FIG. 2A is a schematic cross-sectional view with relevant parts, illustrating an example of a state before bonding of a semiconductor chip. Each of FIGS. 2B and 3 is a schematic cross-sectional view with relevant parts, illustrating an example of a state after bonding of the semiconductor chip. FIG. 3 depicts the density of the conductive particles and the porosity in the sintered member in the example of the state after bonding of the semiconductor chip.

First, the insulated circuit board 10 and the semiconductor chip 30 depicted in FIG. 2A are prepared. In the insulated circuit board 10, the sintered member 20 is disposed on the conductive pattern layer 12, which is provided on one of the main surfaces of the insulating substrate 11. For example, the paste-like sintered member 20 containing conductive particles is placed on the conductive pattern layer 12 of the insulated circuit board 10. Subsequently, the semiconductor chip 30 is arranged such that the bottom face 30b thereof opposes the sintered member 20 on the conductive pattern layer 12. For example, the sintered member 20 disposed on the conductive pattern layer 12 has a planar size larger than that of the bottom face 30b of the semiconductor chip 30, which is set to oppose the sintered member 20. The sintered member 20 arranged on the conductive pattern layer 12 has a thickness in the range of, for example, 130 μm to 140 μm, inclusive. The thickness of the semiconductor chip 30 is, for example, about 100 μm.

The semiconductor chip 30 with the bottom face 30b opposing the sintered member 20 on the conductive pattern layer 12 is brought close to the sintered member 20 so that the bottom face 30b comes into contact with the sintered member 20. Then, pressure is exerted, via the top face 30a of the semiconductor chip 30, on the region of the sintered member 20 in contact with the bottom face 30b of the semiconductor chip 30 toward the conductive pattern layer 12. Herewith, the semiconductor chip 30 is pushed into the sintered member 20 on the conductive pattern layer 12, as illustrated in FIG. 2B. Along with the semiconductor chip 30 being pushed in by the application of pressure, the recess 21 with the semiconductor chip 30 mounted thereon is formed in the sintered member 20. Then, along with the formation of the recess 21, a part of the sintered member 20 extruded around the semiconductor chip 30 forms the frame 22, which shapes the outer edge of the recess 21. The semiconductor chip 30 is pushed into the sintered member 20 such that the top face 30a is located lower, that is, closer to the conductive pattern layer 12 than the top end 22a of the frame 22 of the sintered member 20. For instance, the semiconductor chip 30 is pushed into the sintered member 20 so that the distance between the bottom face 30b (or the recess 21 of the sintered member 20) and the conductive pattern layer 12, i.e., the thickness of the sintered member 20 below the recess 21, is in the range of about 10 μm to 30 μm, inclusive.

The sintered member 20 is heated after or during pressurization of the semiconductor chip 30 against the sintered member 20. The sintered member 20 is preferably heated in an atmosphere of an inert gas, such as nitrogen, when the surface of the conductive pattern layer 12 is not plated. When the surface of the conductive pattern layer 12 is silver-plated, heating of the sintered member 20 may take place in an ambient atmosphere. The heating temperature of the sintered member 20 is set based on the temperature enabling the conductive particles contained in the sintered member 20 to be sintered together. For example, the heating temperature of the sintered member 20 may be in the range of 200° C. to 300° C., inclusive. It is preferably in the range of 220° C. to 280° C., inclusive, and more preferably in the range of 240° C. to 260° C., inclusive.

As mentioned above, pressure is applied to the semiconductor chip 30 to push it into the sintered member 20. Herewith, within the sintered member 20, conductive particles 23 contained in an area AR1, which is located between the conductive pattern layer 12 and the recess 21 with the semiconductor chip 30 mounted thereon, come into contact with each other at a relatively high density, as illustrated in FIG. 3. Heating takes place after or during pressurization of the semiconductor chip 30 against the sintered member 20, which allows the conductive particles 23 in contact with each other at a relatively high density in the area AR1 of the sintered member 20 to be sintered together. Sintering causes the conductive particles 23 to agglomerate to form conductors, which form a conductive path (and a heat conduction path) between the bottom face 30b of the semiconductor chip 30 and the conductive pattern layer 12 of the insulated circuit board 10.

On the other hand, in an area AR2 at the frame 22, which is formed of a part of the sintered member 20 extruded around the semiconductor chip 30 when the semiconductor chip 30 is pressed against the sintered member 20, the conductive particles 23 contained therein are relatively less dense compared to the area AR1. Heating also allows the conductive particles 23 in contact with each other at a relatively low density in the area AR2 of the sintered member 20 to be sintered together, and sintering causes the conductive particles 23 to agglomerate to form conductors. Note that the density of the conductive particles 23 in the area AR2 at the frame 22 of the sintered member 20 before sintering by heating need not necessarily be high like that of the conductive particles 23 in the area AR1 below the recess 21. This is because it is possible to form a conductive path (and a heat conduction path) between the bottom face 30b of the semiconductor chip 30 and the conductive pattern layer 12 of the insulated circuit board 10 in the area AR1 below the recess 21.

In the sintered member 20 after pressurization and heating, void space is formed in the area AR1 between the conductive pattern layer 12 and the recess 21 with the semiconductor chip 30 mounted thereon and in the area AR2 at the frame 22, along with the formation of the conductors achieved by sintering of the conductive particles 23. Note here that, because the area AR1 after pressurization and before heating contains the conductive particles 23 at a relatively high density, the density of the conductors formed in the area AR1 by sintering of the conductive particles 23 through heating is relatively high and therefore void space formed in the area AR1 is relatively small. On the other hand, because the area AR2 after pressurization and before heating contains the conductive particles 23 at a relatively low density, the density of the conductors formed in the area AR2 by sintering of the conductive particles 23 through heating is relatively low and therefore void space formed in the area AR2 is relatively large. As a result, after heating, the porosity of the area AR1 of the sintered member 20 is lower than that of the area AR2, as illustrated in the cross-sectional view of FIG. 3. The area AR1 with relatively low porosity provides a good conductive path (and a good heat conduction path) between the bottom face 30b of the semiconductor chip 30 and the conductive pattern layer 12 of the insulated circuit board 10.

Note that the semiconductor chip bonding process illustrated in FIGS. 2A and 2B is an example of a sintered member shaping process where the semiconductor chip 30 is bonded to the conductive pattern layer 12 of the insulated circuit board 10 using the sintered member 20 and, at the same time, the recess 21 and the frame 22, which shapes the outer edge of the recess 21, are formed in the sintered member 20.

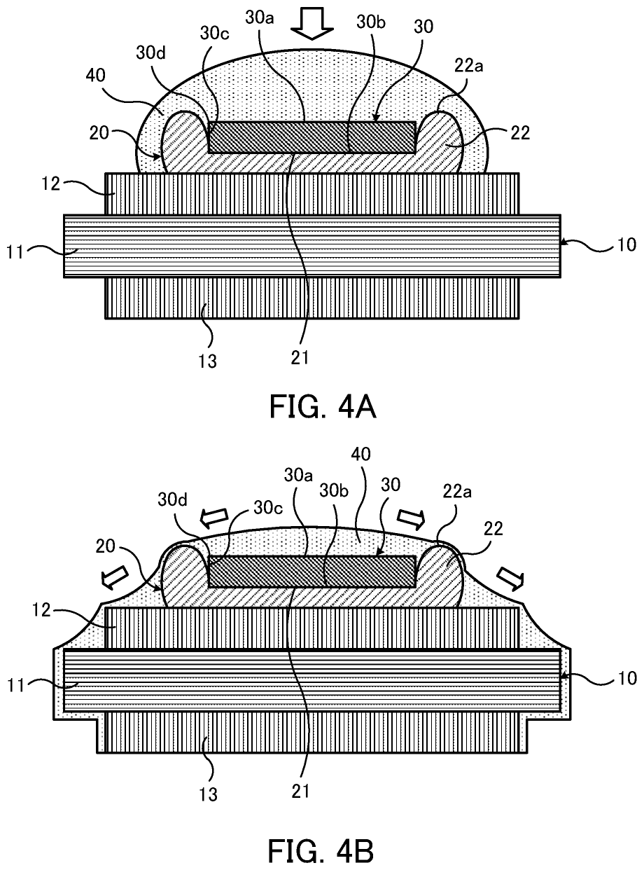

FIGS. 4A and 4B illustrate an example of a coating process according to the first embodiment. FIG. 4A is a schematic cross-sectional view with relevant parts, illustrating an example of a coating material placing process. FIG. 4B is a schematic cross-sectional view with relevant parts, illustrating an example of a coating material flow process.

After pressurization and heating of the sintered member 20, the coating material 40 is placed on the top face 30a side of the semiconductor chip 30, as illustrated in FIG. 4A. Specifically, the coating material 40 has fluidity, and is applied to the top face 30a of the semiconductor chip 30 by means of a dispenser, a spray, or the like, to be placed thereon. Note that the coating material 40 may be placed, not only on the top face 30a of the semiconductor chip 30, but also over the sintered member 20 and the insulated circuit board 10, as illustrated in FIG. 4A.

The coating material 40 placed on the top face 30a side of the semiconductor chip 30 flows and spreads around the semiconductor chip 30 by gravity, as illustrated in FIG. 4B. The viscosity of the coating material 40 to be placed is set such that the coating material 40 spreads around the semiconductor chip 30 after being placed on the semiconductor chip 30. As a result of the coating material 40 thus spreading around the semiconductor chip 30, the semiconductor chip 30 is covered with the coating material 40. The coating material 40 covers, not only the semiconductor chip 30, but also the sintered member 20 and the insulated circuit board 10, as illustrated in FIG. 4B.

Prior to such a coating process, the semiconductor chip 30, on which the coating material 40 is to be placed, is embedded in the sintered member 20 such that the top face 30a is located lower than the top end 22a of the frame 22 of the sintered member 20. Therefore, the frame 22 of the sintered member 20 serves as a dam for the coating material 40, which prevents an excessive outflow of the coating material 40 from the surface of the semiconductor chip 30, and leaves a certain amount of coating material 40 over the semiconductor chip 30. Because the top end 22a of the frame 22 of the sintered member 20 is located higher than the top face 30a of the semiconductor chip 30, the coating material 40 stays inside the frame 22. Hence, the coating material 40 covers, not only the top face 30a of the semiconductor chip 30, but also the lateral face 30c and the corner portion 30d lying between the top face 30a and the lateral face 30c, exposed from the sintered member 20. Herewith, it is possible to prevent the semiconductor chip 30 from being exposed from the coating material 40 and allow the semiconductor chip 30 to be covered with the coating material 40 of sufficient thickness.

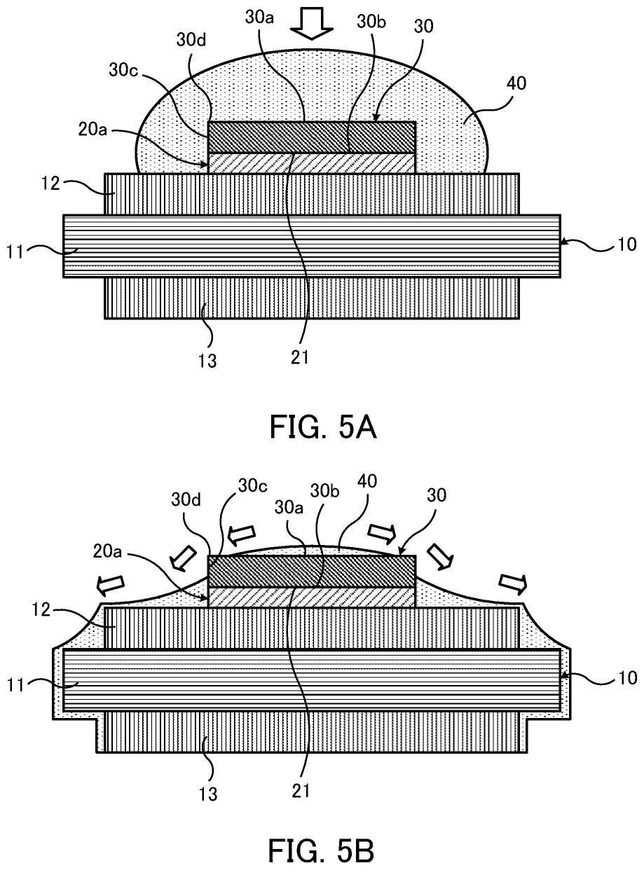

FIGS. 5A and 5B illustrate an example of a coating process according to a different form. FIG. 5A is a schematic cross-sectional view with relevant parts, illustrating an example of a coating material placing process. FIG. 5B is a schematic cross-sectional view with relevant parts, illustrating an example of a coating material flow process.

The form depicted in FIGS. 5A and 5B represents an example where a sintered member 20a is interposed between the bottom face 30b of the semiconductor chip 30 and the conductive pattern layer 12, and the semiconductor chip 30 is not pushed into the sintered member 20a, which therefore does not have the above-described frame 22.

In this form, when the coating material 40 is placed on the top face 30a side of the semiconductor chip 30, as illustrated in FIG. 5A, and the coating material 40 then flows and spreads around the semiconductor chip 30, as illustrated in FIG. 5B, the semiconductor chip 30 may be partially exposed from the coating material 40, or may be covered with the coating material 40 of insufficient thickness. For example, the coating material 40 on the top face 30a of the semiconductor chip 30 may run down from the corner portion 30d to the lateral face 30c, causing the corner portion 30d of the semiconductor chip 30 and its adjacent region to be exposed from the coating material 40 or leaving the coating material 40 with insufficient thickness at and near the corner portion 30d. Such poor formation of the coating material 40 is more likely to occur as the viscosity of the coating material 40 is reduced in order to fully distribute the coating material 40 over the surfaces of the semiconductor chip 30, the sintered member 20, and the insulated circuit board 10.

On the other hand, a certain amount of coating material 40 is trapped within the frame 22 functioning as a dam, which is formed by pushing the semiconductor chip 30 into the sintered member 20 such that the top face 30a is located lower than the top end 22a of the frame 22 of the sintered member 20, as depicted in FIGS. 4A and 4B. This prevents the semiconductor chip 30 from being exposed from the coating material 40 and enables the semiconductor chip 30 to be covered with the coating material 40 of sufficient thickness. That is, it is possible to prevent poor formation of the coating material 40.

The coating material 40 formed to cover the semiconductor chip 30, the sintered member 20, and the insulated circuit board 10 is then cured by a predetermined method, such as heating, according to the material of the coating material 40.

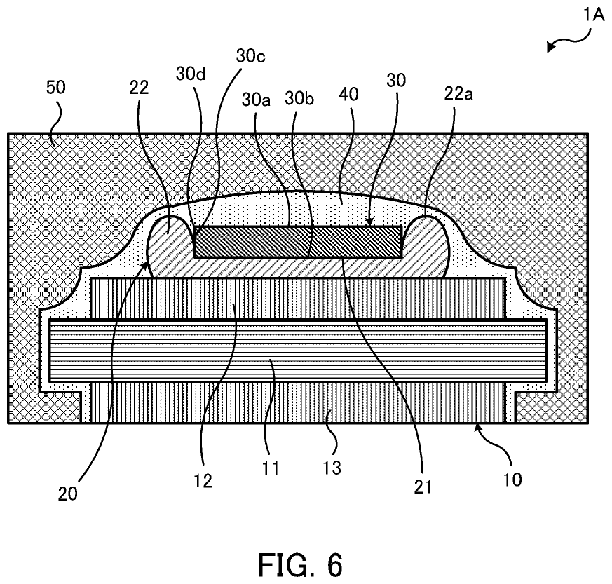

FIG. 6 illustrates an example of a sealing process according to the first embodiment. FIG. 6 is a schematic cross-sectional view with relevant parts, illustrating the example of the sealing process.

After formation of the coating material 40, the insulated circuit board 10, the sintered member 20, the semiconductor chip 30, and the coating material 40 are sealed with a sealant 50, as illustrated in FIG. 6. For example, an epoxy resin composition including an epoxy resin base and a curing agent is used for the sealant 50. The epoxy resin composition of the sealant 50 may contain a filler, using an inorganic material, and other additives. Aliphatic epoxy or alicyclic epoxy is used as the epoxy resin base. A maleimide resin, a cyanate resin, or the like may be used as the sealant 50. Alternatively, two or more kinds of resin materials including an epoxy resin mixed together may be used.

The sealant 50 formed to seal the insulated circuit board 10, the sintered member 20, the semiconductor chip 30, and the coating material 40 is then cured by a predetermined method, such as heating, according to the material of the sealant 50. As a result, the semiconductor device 1A is obtained, in which the insulated circuit board 10, the sintered member 20, the semiconductor chip 30, and the coating material 40 are sealed with the sealant 50, as illustrated in FIG. 6.

In the semiconductor device 1A, the semiconductor chip 30 placed in the recess 21 on the inner side of the frame 22 of the sintered member 20 is not exposed from the coating material 40 and covered with the coating material 40 of sufficient thickness. Therefore, the semiconductor chip 30 and the sealant 50 do not come into direct contact with each other, and the coating material 40 interposed between the semiconductor chip 30 and the sealant 50 enhances their adhesion to each other, which results in relieving stress exerted on them. This prevents, in the semiconductor device 1A, separation of the sealant 50 due to stress caused by temperature loads associated with heat generation during operation and subsequent cooling and the difference in the coefficient of thermal expansion between the semiconductor chip 30 and the sealant 50. By preventing the sealant 50 from being debonded, it is possible to avoid undermining the credibility of the semiconductor chip 30 and the semiconductor device 1A provided with the semiconductor chip 30 and reduce the loss of their insulation performance.

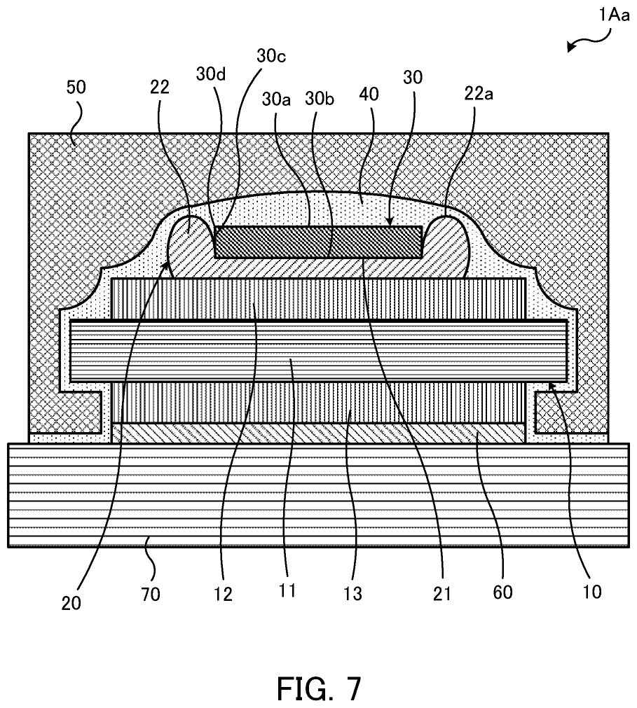

FIG. 7 illustrates another example of the semiconductor device according to the first embodiment. FIG. 7 is a schematic cross-sectional view with relevant parts, illustrating the other example of the semiconductor device.

A semiconductor device 1Aa of FIG. 7 differs from the above-described semiconductor device 1A of FIG. 6 in having a configuration where a substrate 70 is bonded, via a bonding material 60, to the conductive pattern layer 13 side of the insulated circuit board 10, opposite to the conductive pattern layer 12 side on which the sintered member 20 and the semiconductor chip 30 are mounted.

In the case of a vertical element where current flows in the thickness direction of the semiconductor chip 30, a sintered member is used for the bonding material 60. In the case of a horizontal element where current flows in the width direction of the semiconductor chip 30, an electrically conductive adhesive, a compound with good thermal conductivity, or the like may be used for the bonding material 60.

For example, a heat dissipation base is used for the substrate 70. A material used as the heat dissipation base has high thermal conductivity and is hard to warp even after a relatively high temperature treatment, such as bonding using the bonding material 60, and, for example, a copper plate or an aluminum composite silicon carbide plate is used. The heat dissipation base may be provided with a heat dissipation structure, such as cooling fins. In this case, aluminum or the like may be used as the material, other than the above-mentioned materials.

A lead frame may be used for the substrate 70. In this case, the lead frame may be bonded to the conductive pattern layer 13 side of the insulated circuit board 10 via the bonding material 60, and the semiconductor chip 30 mounted on the conductive pattern layer 12 side of the insulated circuit board 10 via the sintered member 20 may be then connected to the lead frame by means of conductive members, such as wires and clips, to thereby form a circuit including the lead frame and the like.

In the case of bonding the substrate 70 to the conductive pattern layer 13 side of the insulated circuit board 10 via the bonding material 60, as in the semiconductor device 1Aa, the substrate 70 is bonded via the bonding material 60 before or after bonding of the semiconductor chip 30 (FIGS. 2A and 2B, respectively) in the semiconductor chip bonding process (i.e., the sintered member shaping process) depicted in FIGS. 2A and 2B above. Alternatively, the substrate 70 may be bonded via the bonding material 60 after the flow and curing of the coating material 40 (FIG. 4B) in the coating process depicted in FIGS. 4A and 4B above. The structure made up of the insulated circuit board 10, the sintered member 20, the semiconductor chip 30, and the coating material 40 covering them is mounted on the substrate 70 via the bonding material 60 and then sealed with the sealant 50, to thereby obtain the semiconductor device 1Aa of FIG. 7.

Also in the case of the semiconductor device 1Aa, the semiconductor chip 30 is covered with the coating material 40 of sufficient thickness. This, therefore, prevents separation of the sealant 50 due to stress caused by temperature loads during operation and the difference in the coefficient of thermal expansion between the semiconductor chip 30 and the sealant 50. As a result, it is possible to avoid undermining the credibility of the semiconductor chip 30 and the semiconductor device 1Aa provided with the semiconductor chip 30 and reduce the loss of their insulation performance.

Next described are modifications related to the formation of the above-described semiconductor device 1A and the like.

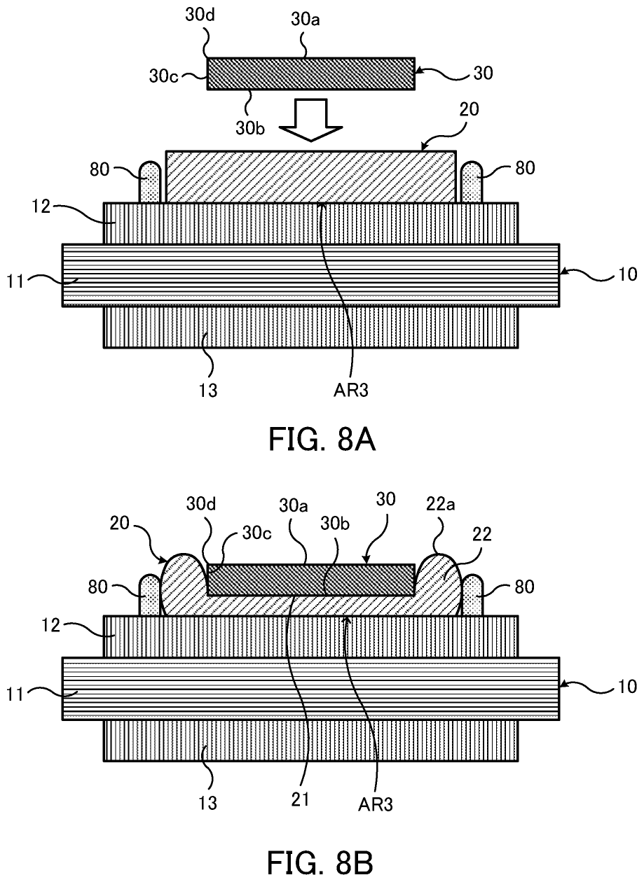

FIGS. 8A and 8B illustrate a first modification of the semiconductor device formation according to the first embodiment. FIG. 8A is a schematic cross-sectional view with relevant parts, illustrating an example of a state before bonding of a semiconductor chip. FIG. 8B is a schematic cross-sectional view with relevant parts, illustrating an example of a state after bonding of the semiconductor chip.

A stretch of protrusion 80 arranged uninterruptedly, or a plurality of protrusions 80 arranged intermittently, may be provided, on the conductive pattern layer 12 of the insulated circuit board 10, on the outer side of an area AR3 where the sintered member 20 is to be disposed, in such a manner as to surround the area AR3, as illustrated in FIG. 8A. The protrusion 80 is formed, for example, using a resin material, such as an epoxy resin. For example, a predetermined resin material is placed on the conductive pattern layer 12 of the insulated circuit board 10 by means of a dispenser or the like and then cured, to thereby form the protrusion 80.

Subsequently, the sintered member 20 is disposed, on the conductive pattern layer 12 of the insulated circuit board 10, in the area AR3 on the inner side of the protrusion 80, and the semiconductor chip 30 with the bottom face 30b opposing the sintered member 20 is brought close to the sintered member 20, as illustrated in FIG. 8A. Then, pressure is exerted, via the top face 30a of the semiconductor chip 30, on the region of the sintered member 20 in contact with the bottom face 30b of the semiconductor chip 30 toward the conductive pattern layer 12. As a result, the semiconductor chip 30 is pushed into the sintered member 20 on the conductive pattern layer 12, as illustrated in FIG. 8B. Herewith, the recess 21 with the semiconductor chip 30 mounted therein is formed in the sintered member 20. Along with the formation of the recess 21, a part of the sintered member 20 extruded around the semiconductor chip 30 forms the frame 22. The semiconductor chip 30 is pushed into the sintered member 20 such that the top face 30a is located lower than the top end 22a of the frame 22.

When the semiconductor chip 30 is pushed into the sintered member 20, the protrusion 80 located outside of the sintered member 20 acts as a wall, and the part of the sintered member 20 extruded around the semiconductor chip 30 is prevented from spreading laterally (i.e., in the direction parallel to the conductive pattern layer 12) and, therefore, easily raised upward (in the direction perpendicular to the conductive pattern layer 12). That is, the protrusion 80 functions as a dam for trapping the sintered member 20 on its inner side. The protrusion 80 acting as a dam for the sintered member 20 facilitates obtaining the structure where the top end 22a of the frame 22 is located higher than the top face 30a of the semiconductor chip 30.

Note that the semiconductor chip 30, the protrusion 80, the sintered member 20, and the insulated circuit board 10 arranged as illustrated in FIG. 8B are covered with the coating material 40 and then sealed with the sealant 50, according to the example described above.

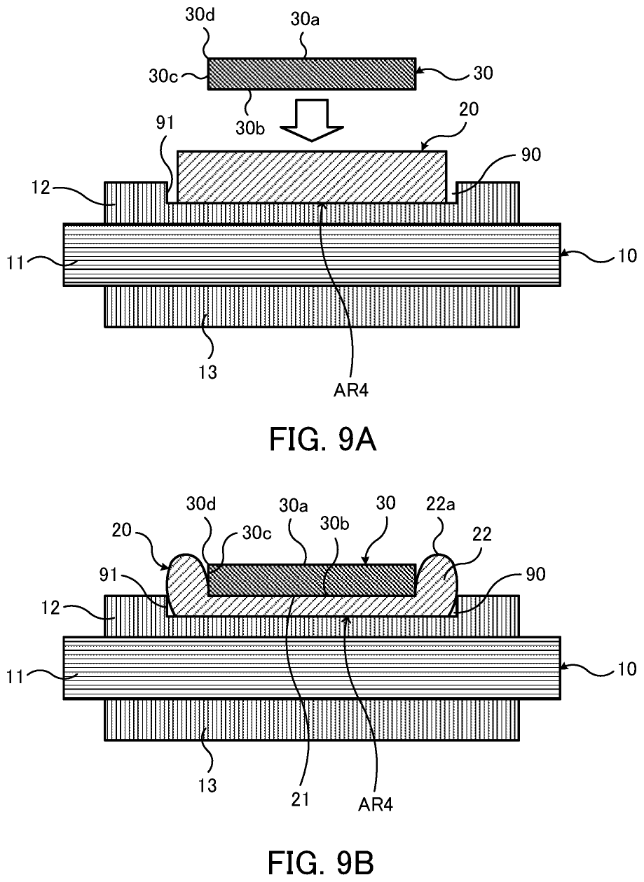

FIGS. 9A and 9B illustrate a second modification of the semiconductor device formation according to the first embodiment. FIG. 9A is a schematic cross-sectional view with relevant parts, illustrating an example of a state before bonding of a semiconductor chip. FIG. 9B is a schematic cross-sectional view with relevant parts, illustrating an example of a state after bonding of the semiconductor chip.

A concave pit 90 may be provided, in the conductive pattern layer 12 of the insulated circuit board 10, in an area AR4 where the sintered member 20 is to be disposed, as illustrated in FIG. 9A. The concave pit 90 is formed by, for example, etching on the surface of the conductive pattern layer 12.

The sintered member 20 is disposed in the area AR4 of the concave pit 90 provided in the conductive pattern layer 12 of the insulated circuit board 10, and the semiconductor chip 30 with the bottom face 30b opposing the sintered member 20 is then brought close to the sintered member 20, as illustrated in FIG. 9A. Subsequently, pressure is exerted, via the top face 30a of the semiconductor chip 30, on the region of the sintered member 20 in contact with the bottom face 30b of the semiconductor chip 30 toward the conductive pattern layer 12. As a result, the semiconductor chip 30 is pushed into the sintered member 20 on the conductive pattern layer 12, as illustrated in FIG. 9B. Herewith, the recess 21 with the semiconductor chip 30 mounted therein is formed in the sintered member 20. Along with the formation of the recess 21, a part of the sintered member 20 extruded around the semiconductor chip 30 forms the frame 22. The semiconductor chip 30 is pushed into the sintered member 20 such that the top face 30a is located lower than the top end 22a of the frame 22.

When the semiconductor chip 30 is pushed into the sintered member 20, the part of the sintered member 20 extruded around the semiconductor chip 30 is prevented from spreading laterally by an inner wall 91 of the concave pit 90 of the conductive pattern layer 12 and, therefore, easily raised upward. That is, the inner wall 91 of the concave pit 90 functions as a dam for trapping the sintered member 20 on its inner side. The inner wall 91 of the concave pit 90 functioning as a dam for the sintered member 20 facilitates obtaining the structure where the top end 22a of the frame 22 is located higher than the top face 30a of the semiconductor chip 30.

Note that the semiconductor chip 30, the sintered member 20, and the insulated circuit board 10 arranged as illustrated in FIG. 9B are covered with the coating material 40 and then sealed with the sealant 50, according to the example described above.

Further, the protrusion 80 of FIGS. 8A and 8B above may be formed, on the conductive pattern layer 12 with the concave pit 90 of FIGS. 9A and 9B provided therein, on the outer side of the area AR4 where the sintered member 20 is to be disposed. Herewith, the inner wall 91 of the concave pit 90 and the protrusion 80 function as a dam, which prevents the sintered member 20 from spreading laterally and helps it rise upward. Thus, it becomes even easier to obtain the structure where the top end 22a of the frame 22 is located higher than the top face 30a of the semiconductor chip 30.

### (b) Second Embodiment

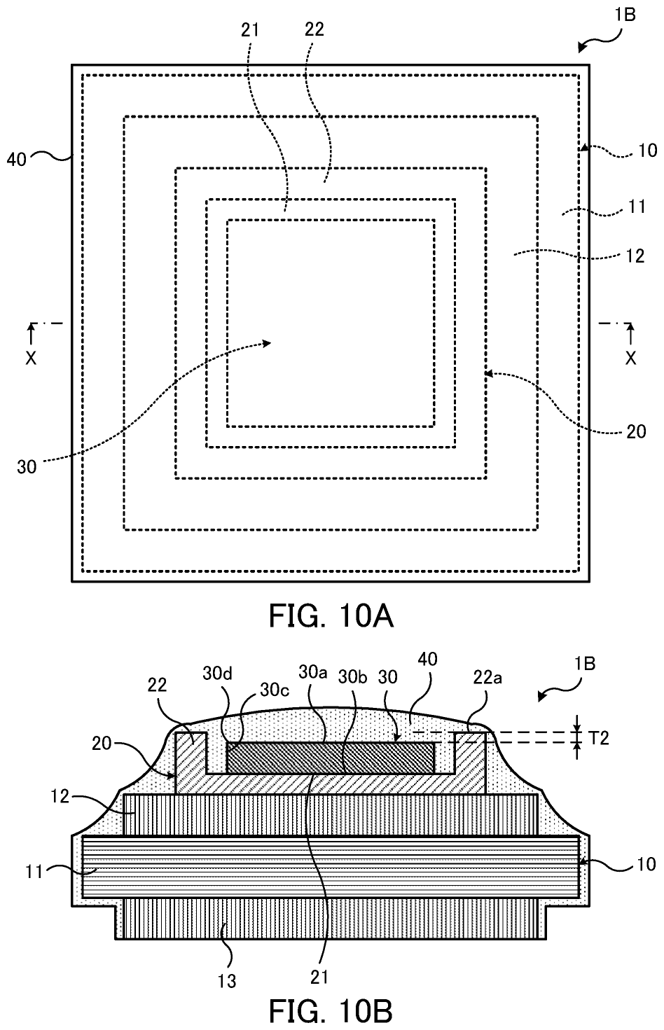

FIGS. 10A and 10B illustrate an example of a semiconductor device according to a second embodiment. FIG. 10A is a schematic plan view with relevant parts of the semiconductor device, and FIG. 10B is a schematic cross-sectional view with relevant parts of the semiconductor device. FIG. 10B is a cross-sectional view of the semiconductor device along X-X of FIG. 10A.

A semiconductor device 1B of FIGS. 10A and 10B includes the insulated circuit board 10, the sintered member 20, the semiconductor chip 30, and the coating material 40. The sintered member 20 of the semiconductor device 1B includes the recess 21, on which the semiconductor chip 30 is mounted, and the frame 22 shaping the outer edge of the recess 21. The inner wall of the frame 22 (or the recess 21) has a shape that does not come into contact with the lateral face 30c of the semiconductor chip 30. The semiconductor device 1B differs from the semiconductor device 1A of the first embodiment above in having such a sintered member 20.

In the semiconductor device 1B, the semiconductor chip 30 is embedded in the sintered member 20 such that the top face 30a, the lateral face 30c, and the corner portion 30d are exposed from the sintered member 20, and the top end 22a of the frame 22 is located higher than the top face 30a of the semiconductor chip 30. FIG. 10B illustrates a case where the semiconductor chip 30 is embedded in the sintered member 20 so that the top face 30a of the semiconductor chip 30 is located lower and closer to the conductive pattern layer 12, by a height difference T2, than the top end 22a of the frame 22 of the sintered member 20.

The semiconductor chip 30, the sintered member 20, and the insulated circuit board 10 thus arranged are covered with the coating material 40. In the semiconductor device 1B, because the top face 30a of the semiconductor chip 30 is located closer to the conductive pattern layer 12 than the top end 22a of the frame 22 of the sintered member 20, the coating material 40 is trapped inside the frame 22 (the recess 21), as in the semiconductor device 1A above. This prevents the semiconductor chip 30 (including the top face 30a, the lateral face 30c, and the corner portion 30d lying between the top face 30a and the lateral face 30c) from being exposed from the coating material 40.

Next described is a method of formation of the semiconductor device 1B having the above-described configuration.

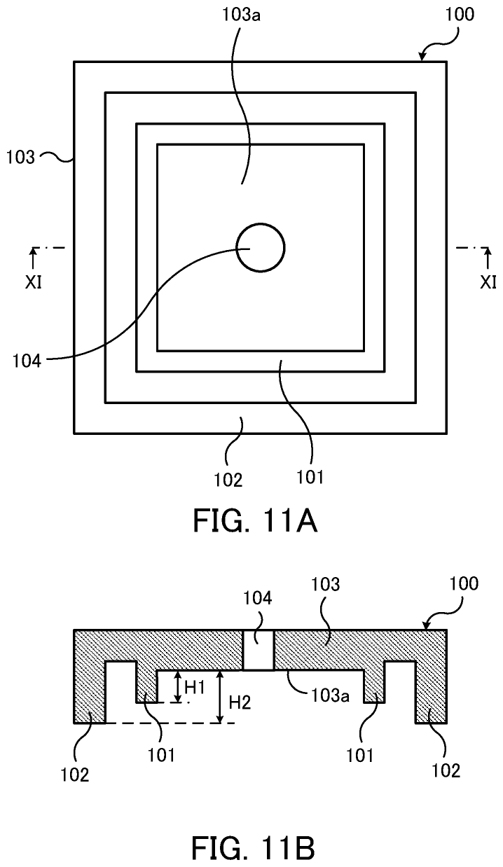

FIGS. 11A and 11B illustrate an example of a jig used to form the semiconductor device according to the second embodiment. FIG. 11A is a schematic plan view with relevant parts of the example of the jig, and FIG. 11B is a schematic cross-sectional view with relevant parts of the example of the jig. FIG. 11B is a cross-sectional view of the jig along XI-XI of FIG. 11A.

A jig 100 illustrated in FIGS. 11A and 11b is used to form the semiconductor device 1B. The jig 100 includes a plate portion 103, and a surrounding portion 101 (a first surrounding portion) and a surrounding portion 102 (a second surrounding portion) provided on one surface (inner surface) 103a of the plate portion 103. Note that FIG. 11A is a plan view of the jig 100 viewed from the inner surface 103a side of the plate portion 103, on which the surrounding portions 101 and 102 are provided. The jig 100 further includes a through hole 104 provided, on the plate portion 103, on the inner side of the surrounding portion 101.

The surrounding portion 101 of the jig 100 protrudes at a height H1 from the inner surface 103a of the plate portion 103. The surrounding portion 102 of the jig 100 is provided, on the inner surface 103a of the plate portion 103, on the outer side of the surrounding portion 101 and protrudes from the inner surface 103a at a height H2, which is higher than the height H1 of the surrounding portion 101. On the inside of the surrounding portion 101 of the jig 100, the semiconductor chip 30 is held when the semiconductor device 1B is formed, as described later. The surrounding portion 102 is provided with a given space away from the surrounding portion 101 positioned on the inner side of the surrounding portion 102. The inner surface 103a between the surrounding portions 101 and 102 is located at a deeper level than the inner surface 103a laid on the inner side of the surrounding portion 101, as viewed from the inner surface 103a side. The jig 100 may be formed of various materials, such as metal, ceramic, carbon, and resin.

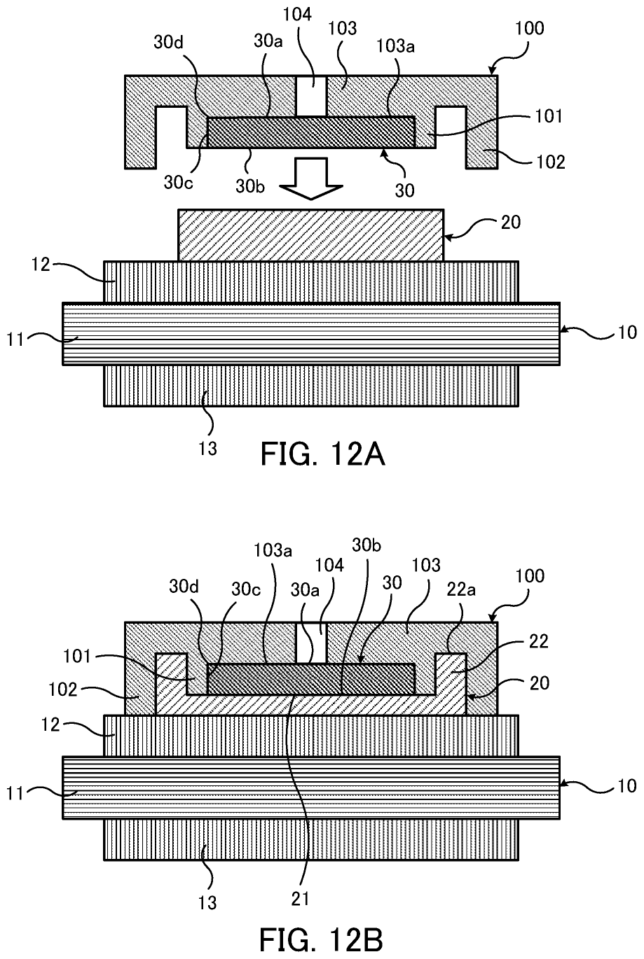

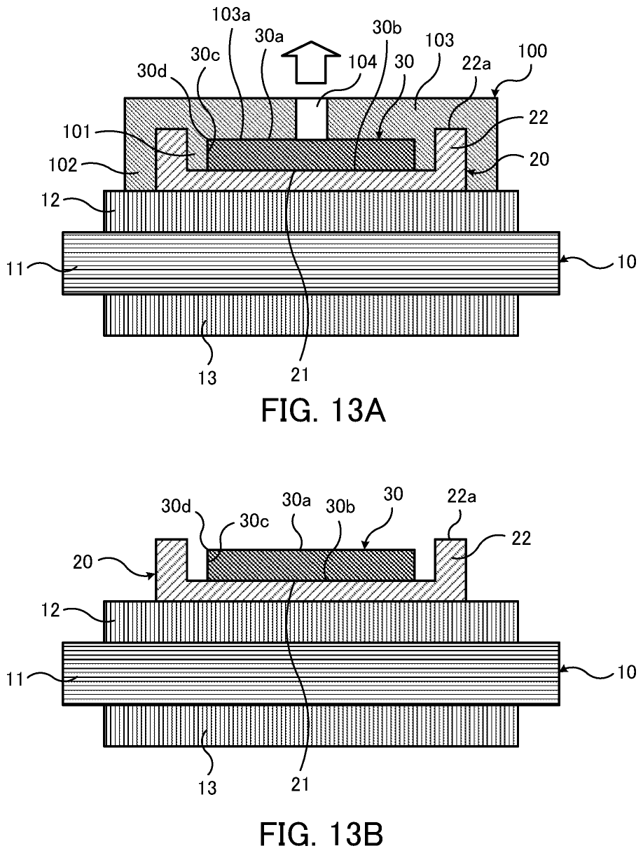

FIGS. 12A, 12B, 13A, and 13B illustrate an example of a semiconductor chip bonding process according to the second embodiment. FIG. 12A is a schematic cross-sectional view with relevant parts, illustrating an example of a state before bonding of a semiconductor chip. FIG. 12B is a schematic cross-sectional view with relevant parts, illustrating an example of a jig abutting process. FIG. 13A is a schematic cross-sectional view with relevant parts, illustrating an example of a jig separation process. FIG. 13B is a schematic cross-sectional view with relevant parts, illustrating an example of a state after bonding of the semiconductor chip.

In bonding the semiconductor chip 30 to the sintered member 20 disposed on the conductive pattern layer 12 of the insulated circuit board 10, the semiconductor chip 30 is held inside the surrounding portion 101 of the jig 100 such that the top face 30a of the semiconductor chip 30 and the inner surface 103a of the plate portion 103 of the jig 100 oppose each other, as illustrated in FIG. 12A. At that time, the semiconductor chip 30 adsorbs onto the inner surface 103a by negative pressure generated inside the through hole 104 by suction through a nozzle tip of a chip mounter, which is set on the surface opposite to the inner surface 103a of the jig 100. In this manner, the semiconductor chip 30 is held inside the surrounding portion 101 of the jig 100.

The jig 100 with the semiconductor chip 30 held therein is transferred by the chip mounter and brought closer toward the conductive pattern layer 12 of the insulated circuit board 10 and the sintered member 20 disposed on the conductive pattern layer 12. Then, by pressurization, the surrounding portion 102 located on the outer side of the surrounding portion 101 holding the semiconductor chip 30 therein abuts on the conductive pattern layer 12, as illustrated in FIG. 12B. In the course of the procedure, the semiconductor chip 30 and the surrounding portion 101 holding thereof are pushed into the sintered member 20, and thereby the recess 21 is formed in the sintered member 20. Then, a part of the sintered member 20 extruded around the semiconductor chip 30 along with the formation of the recess 21 is extruded into and fills the gap between the surrounding portion 101 holding the semiconductor chip 30 and the surrounding portion 102 laid outside of the surrounding portion 101. Herewith, the frame 22 is formed in the sintered member 20.

As for the heights from the inner surface 103a of the plate portion 103, the surrounding portion 101 holding the semiconductor chip 30 is set lower than the surrounding portion 102 laid outside of the surrounding portion 101. This allows a part of the sintered member 20 to be extruded from the region sandwiched between the semiconductor chip 30 and the conductive pattern layer 12 into the gap between the surrounding portions 101 and 102 until the surrounding portion 102 is made to abut on the conductive pattern layer 12. Further, the inner surface 103a between the surrounding portions 101 and 102 of the jig 100 is positioned at a deeper level than the inner surface 103a laid on the inner side of the surrounding portion 101, as viewed from the inner surface 103a side, and the semiconductor chip 30 is held inside the surrounding portion 101. Herewith, the top end 22a of the frame 22 formed when the surrounding portion 102 abuts on the conductive pattern layer 12 is set at a position higher than the top face 30a of the semiconductor chip 30.

After or while the semiconductor chip 30 is pressed against the sintered member 20 by means of the jig 100, the sintered member 20 is heated. Herewith, conductive particles in contact with each other in the sintered member 20 are sintered together, and a conductive path (and a heat conduction path) is formed between the bottom face 30b of the semiconductor chip 30 and the conductive pattern layer 12 of the insulated circuit board 10. As for the porosity of the sintered member 20 after conductive particles are sintered together by heating, the region between the recess 21 with the semiconductor chip 30 mounted therein and the conductive pattern layer 12 may have lower porosity than the frame 22, as described in FIG. 3 above.

After pressing the semiconductor chip 30 against the sintered member 20 using the jig 100 and heating the sintered member 20, the jig 100 is separated from the semiconductor chip 30, the sintered member 20, and the conductive pattern layer 12, as illustrated in FIG. 13A. At that time, the semiconductor chip 30 becomes releasable from the inner surface 103a by positive pressure, which is generated inside the through hole 104 by releasing the suction (the negative pressure inside the through hole 104) through the nozzle tip of the chip mounter set on the surface opposite to the inner surface 103a of the jig 100. From this state, the jig 100 is lifted and separated from the semiconductor chip 30, the sintered member 20, and the conductive pattern layer 12. As a result, the structure illustrated in FIG. 13B is obtained.

The semiconductor chip bonding process illustrated in FIGS. 12A, 12B, 13A, and 13B is an example of the sintered member shaping process where the semiconductor chip 30 is bonded to the conductive pattern layer 12 using the sintered member 20 and, at the same time, the recess 21 and the frame 22 shaping the outer edge of the recess 21 are formed in the sintered member 20.

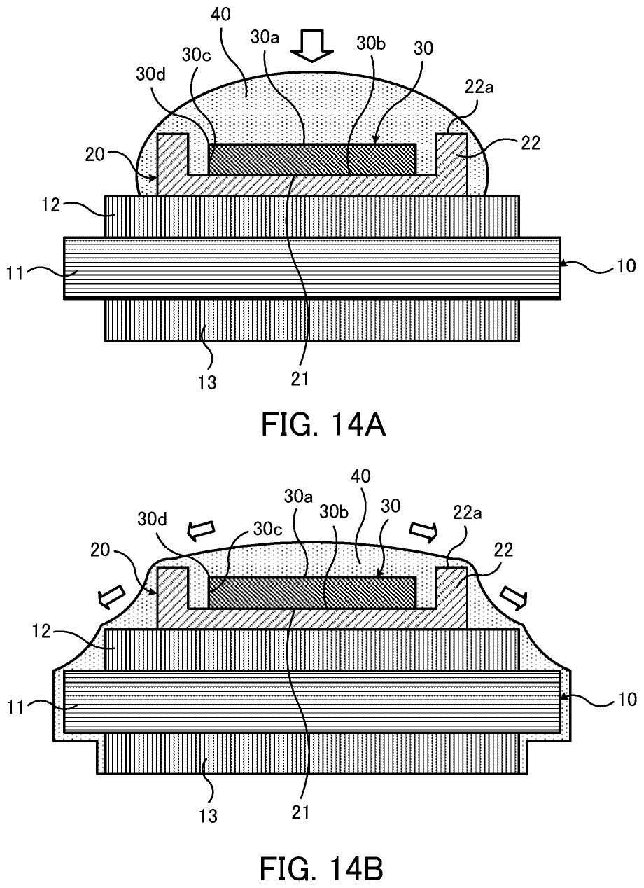

FIGS. 14A and 14B illustrate an example of a coating process according to the second embodiment. FIG. 14A is a schematic cross-sectional view with relevant parts, illustrating an example of a coating material placing process. FIG. 14B is a schematic cross-sectional view with relevant parts, illustrating an example of a coating material flow process.

After separation of the jig 100, the coating material 40 is applied to the top face 30a of the semiconductor chip 30 by means of a dispenser, a spray, or the like, to be thereby placed thereon, as illustrated in FIG. 14A. Note that the coating material 40 may be placed, not only on the semiconductor chip 30, but also over the sintered member 20 and the insulated circuit board 10. The coating material 40 placed on the top face 30a side of the semiconductor chip 30 flows and spreads around the semiconductor chip 30 by gravity, as illustrated in FIG. 14B. As a result of the coating material 40 thus spreading around the semiconductor chip 30, the semiconductor chip 30 is covered with the coating material 40. The coating material 40 covers, not only the semiconductor chip 30, but also the sintered member 20 and the insulated circuit board 10.

In such a coating process, the semiconductor chip 30, on which the coating material 40 is to be placed, is embedded in the sintered member 20 such that the top face 30a is located lower than the top end 22a of the frame 22 of the sintered member 20. Therefore, the frame 22 of the sintered member 20 serves as a dam for the coating material 40, which prevents an excessive outflow of the coating material 40 from the surface of the semiconductor chip 30, and leaves a certain amount of coating material 40 over the semiconductor chip 30 and the peripheral region (the gap between the lateral face 30c and the frame 22). Because the top end 22a of the frame 22 of the sintered member 20 is located higher than the top face 30a of the semiconductor chip 30 and the coating material 40 therefore stays inside the frame 22, the top face 30a of the semiconductor chip 30 as well as the lateral face 30c and the corner portion 30d is covered with the coating material 40. Herewith, it is possible to prevent the semiconductor chip 30 from being exposed from the coating material 40 and allow the semiconductor chip 30 to be covered with the coating material 40 of sufficient thickness.

The coating material 40 formed to cover the semiconductor chip 30, the sintered member 20, and the insulated circuit board 10 is then cured by a predetermined method, such as heating, according to the material of the coating material 40.

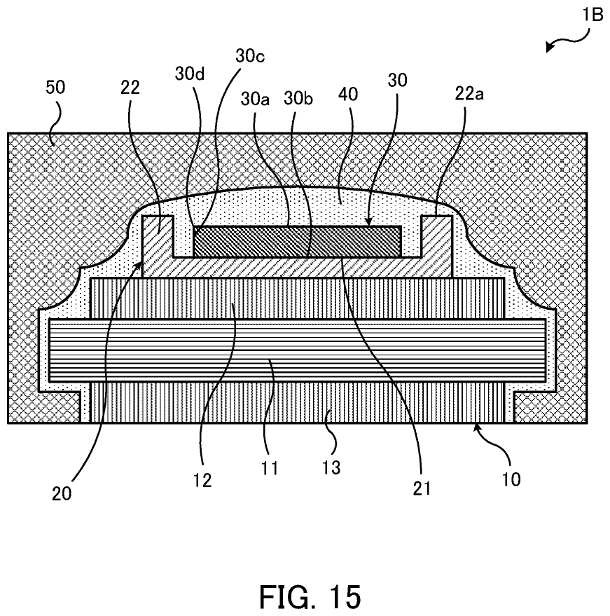

FIG. 15 illustrates an example of a sealing process according to the second embodiment. FIG. 15 is a schematic cross-sectional view with relevant parts, illustrating the example of the sealing process.

After formation of the coating material 40, the insulated circuit board 10, the sintered member 20, the semiconductor chip 30, and the coating material 40 are sealed with the sealant 50, as illustrated in FIG. 15. The sealant 50 is then cured by a predetermined method, such as heating, according to the material of the sealant 50. As a result, the semiconductor device 1B illustrated in FIG. 15 is obtained.

In the semiconductor device 1B, the semiconductor chip 30 mounted in the recess 21 on the inner side of the frame 22 of the sintered member 20 is not exposed from the coating material 40 and covered with the coating material 40 of sufficient thickness. Therefore, the semiconductor chip 30 and the sealant 50 do not come into direct contact with each other, and the coating material 40 interposed between the semiconductor chip 30 and the sealant 50 enhances their adhesion to each other, which results in relieving stress exerted on them. This prevents, in the semiconductor device 1B, separation of the sealant 50 due to stress caused by temperature loads associated with heat generation during operation and subsequent cooling and the difference in the coefficient of thermal expansion between the semiconductor chip 30 and the sealant 50. By preventing the sealant 50 from being debonded, it is possible to avoid undermining the credibility of the semiconductor chip 30 and the semiconductor device 1B provided with the semiconductor chip 30 and reduce the loss of their insulation performance.

As for the insulated circuit board 10 of the semiconductor device 1B, the substrate 70, such as a heat dissipation base or a lead frame, may be bonded via the bonding material 60 to the conductive pattern layer 13, which is located on the opposite side from the conductive pattern layer 12 where the sintered member 20 and the semiconductor chip 30 are mounted.

Next described are modifications of the jig 100 used to form the above-described semiconductor device 1B and the like.

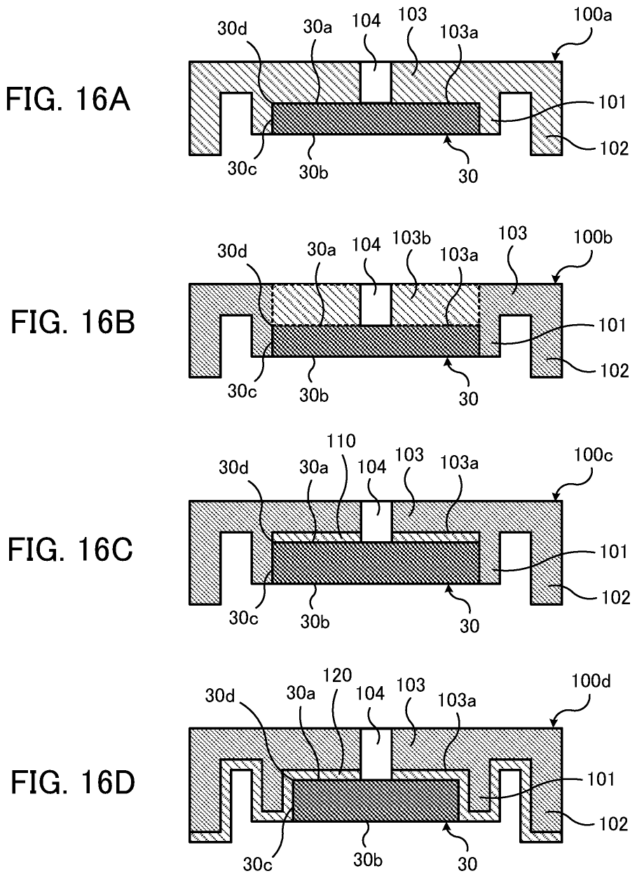

FIGS. 16A to 16D illustrate modifications of the jig according to the second embodiment. Each of FIGS. 16A to 16D is a schematic cross-sectional view with relevant parts of an example of a jig with a semiconductor chip held therein.

A jig 100a of FIG. 16A is an example of a jig made of a material softer than the semiconductor chip 30. In the jig 100a, the plate portion 103, the surrounding portion 101, and the surrounding portion 102 are formed of a soft material, and the through hole 104 for suction retention and release of the semiconductor chip 30 is provided in the plate portion 103. For example, the jig 100a is formed using a silicone resin, a polyimide resin, graphite and the like. The top face 30a of the semiconductor chip 30 is provided with, for example, terminals for electrically connecting the semiconductor chip 30 to other parts; and a protective film (passivation film) for protecting the top face 30a except for exposed portions of the terminals. Therefore, the top face 30a of the semiconductor chip 30 may be uneven. The use of the jig 100a softer than the semiconductor chip 30 to hold the semiconductor chip 30 with the top face 30a possibly having bumps and dips allows, when the top face 30a of the semiconductor chip 30 and the inner surface 103a of the plate portion 103 opposing each other come into contact, the flexible inner surface 103a to absorb the unevenness of the top face 30a. Further, the use of the jig 100a softer than the semiconductor chip 30 prevents the semiconductor chip 30 from being damaged by collision with the plate portion 103 and the surrounding portion 101 at the time of holding the semiconductor chip 30.

A jig 100b of FIG. 16B is an example of a jig where, within the plate portion 103, a region 103b located on the inner side of the surrounding portion 101 with the semiconductor chip 30 held therein is made of a soft material. In the jig 100b, the through hole 104 for suction retention and release of the semiconductor chip 30 is provided in the region 103b made of the soft material. For example, the region 103b of the jig 100b is formed using a silicone resin, a polyimide resin, graphite and the like. By the use of the jig 100b having the flexible region 103b, it is also possible to absorb the unevenness of the top face 30a of the semiconductor chip 30. Further, the use of the jig 100b prevents the semiconductor chip 30 from being damaged by collision with the plate portion 103 at the time of holding the semiconductor chip 30.

A jig 100c of FIG. 16C is an example of a jig where a layer 110 formed of a soft material is provided inside the surrounding portion 101 where the semiconductor chip 30 is held. In the jig 100c, the through hole 104 for suction retention and release of the semiconductor chip 30 is provided in the plate portion 103 on the inner side of the surrounding portion 101 and the layer 110 formed thereon. For example, the layer 110 of the jig 100c is formed using a silicone resin, a polyimide resin, graphite and the like. By the use of the jig 100c having the flexible layer 110, it is also possible to absorb the unevenness of the top face 30a of the semiconductor chip 30. Further, the layer 110 prevents the semiconductor chip 30 from being damaged by collision at the time of holding the semiconductor chip 30.

A jig 100d of FIG. 16D is an example of a jig where a layer 120 formed of a soft material is provided in such a manner as to cover the inner surface 103a side of the plate portion 103, on which the surrounding portions 101 and 102 are provided. In the jig 100d, the through hole 104 for suction retention and release of the semiconductor chip 30 is provided in the plate portion 103 on the inner side of the surrounding portion 101 and the layer 120 formed thereon. For example, the layer 120 of the jig 100d is formed using a silicone resin, a polyimide resin, graphite and the like. By the use of the jig 100d having the flexible layer 120, it is also possible to absorb the unevenness of the top face 30a of the semiconductor chip 30. Further, the layer 120 prevents the semiconductor chip 30 from being damaged by collision at the time of holding the semiconductor chip 30. In addition, the layer 120 may be made of a material having low adhesion to the sintered member 20. In this case, in separating the jig 100d with the semiconductor chip 30 held therein (FIGS. 13A and 13B) after the jig 100d is pressed toward the sintered member 20 on the insulated circuit board 10, the layer 120 provides better separation, that is, facilitates debonding of the jig 100d from the sintered member 20.

### (c) Third Embodiment

Next described is an example of a manufacturing method of the above-described semiconductor devices 1A, 1B, and the like as a third embodiment.

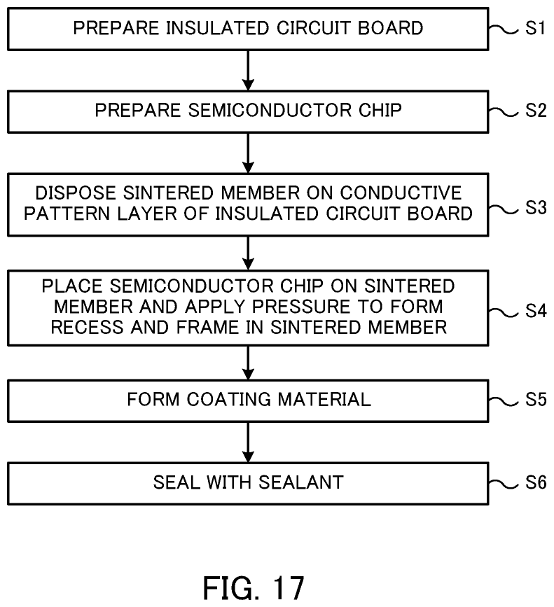

FIG. 17 illustrates an example of a semiconductor device manufacturing method according to the third embodiment.

In manufacturing the semiconductor devices 1A, 1B, and the like, the insulated circuit board 10 is prepared where the conductive pattern layers 12 and 13 are individually provided on one of both main surfaces of the insulating substrate 11 (step S1). The semiconductor chip 30 to be mounted on the insulated circuit board 10 is prepared (step S2). Note that the order of steps S1 and S2 does not matter.

The sintered member 20 is disposed on the conductive pattern layer 12 of the prepared insulated circuit board 10 (step S3). In the case of providing the conductive pattern layer 12 with the protrusion 80 functioning as a dam for the sintered member 20 (FIGS. 8A and 8B), the protrusion 80 is formed on the conductive pattern layer 12 prior to disposition of the sintered member 20 on the conductive pattern layer 12, and then the sintered member 20 is disposed inside the formed protrusion 80. In the case of providing the conductive pattern layer 12 with the concave pit 90 functioning as a dam for the sintered member 20 (FIGS. 9A and 9B), the concave pit 90 is formed on the conductive pattern layer 12 prior to disposition of the sintered member 20 on the conductive pattern layer 12, and then the sintered member 20 is disposed inside the formed concave pit 90.

Subsequently, the prepared semiconductor chip 30 is placed on the sintered member 20 disposed on the conductive pattern layer 12, and pressure is applied to thereby form the recess 21 and the frame 22 in the sintered member 20 (step S4). Specifically, the bottom face 30b of the semiconductor chip 30 is placed on the sintered member 20, and pressure is exerted, via the top face 30a of the semiconductor chip 30, on a region of the sintered member 20 in contact with the bottom face 30b of the semiconductor chip 30 toward the conductive pattern layer 12. Herewith, the recess 21 with the semiconductor chip 30 mounted therein is formed in the sintered member 20. Along with this, the frame 22 is created, which shapes the outer edge of the recess 21 and has the top end 22a located higher than the top face 30a of the semiconductor chip 30. In order to pressurize the semiconductor chip 30 and the sintered member 20, to thereby form the recess 21 and the frame 22 in the sintered member 20, the jig 100 illustrated in FIGS. 11A and 11B, and the like, may be used. After or during pressurization of the semiconductor chip 30 against the sintered member 20, the sintered member 20 is heated. Herewith, the conductive particles 23 contained in the sintered member 20 are sintered together.

After pressurization and heating of the sintered member 20, the coating material 40 is formed in such a manner as to cover the semiconductor chip 30, the sintered member 20, and the insulated circuit board 10 (step S5). At that time, because the top face 30a of the semiconductor chip 30 is located closer to the conductive pattern layer 12 than the top end 22a of the frame 22 of the sintered member 20, the coating material 40 is trapped inside the frame 22 (the recess 21). This prevents the semiconductor chip 30 (including the top face 30a, the lateral face 30c, and the corner portion 30d lying between the top face 30a and the lateral face 30c) from being exposed from the coating material 40. The coating material 40 covering the semiconductor chip 30 is cured by, for example, heating.

In the case of bonding the substrate 70, such as a heat dissipation base or a lead frame, to the conductive pattern layer 13 of the insulated circuit board 10 via the bonding material 60 (FIG. 7), the substrate 70 is bonded, via the bonding material 60, to the conductive pattern layer 13 prior to or after placement of the semiconductor chip 30 (FIGS. 2A and 2B) in step S4, or after formation of the coating material 40 (FIGS. 4A and 4B) in step S5.

After formation of the coating material 40, the insulated circuit board 10, the sintered member 20, the semiconductor chip 30, and the coating material 40 are sealed with the sealant 50 (step S6). Herewith, the above-described semiconductor device 1A, 1B, or the like is obtained.

In the semiconductor devices 1A, 1B, and the like, the semiconductor chip 30 placed in the recess 21 on the inner side of the frame 22 of the sintered member 20 is not exposed from the coating material 40 and covered with the coating material 40 of sufficient thickness. Therefore, the coating material 40 interposed between the semiconductor chip 30 and the sealant 50 enhances their adhesion to each other, which results in relieving stress exerted on them. This prevents separation of the sealant 50 due to stress caused by temperature loads during operation and the difference in the coefficient of thermal expansion between the semiconductor chip 30 and the sealant 50. By preventing the sealant 50 from being debonded, it is possible to avoid undermining the credibility of the semiconductor chip 30 and the semiconductor devices 1A, 1B, and the like provided with the semiconductor chip 30 and reduce the loss of their insulation performance.

According to one aspect, it is possible to provide a semiconductor device where poor formation of a coating material covering a semiconductor chip is prevented.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
an insulated circuit board including a conductive pattern layer;
a sintered member disposed on the conductive pattern layer, the sinter member having a frame formed on a surface thereof opposite to the conductive pattern layer, to thereby form a recess on the surface, the frame shaping an outer edge of the recess;
a semiconductor chip having a top face, a bottom face opposite to the top face, and a lateral face, the semiconductor chip being mounted in the recess with the bottom face opposing the recess, the top face being located closer to the conductive pattern layer than a top end of the frame; and
a coating material covering the semiconductor chip mounted in the recess.

2. The semiconductor device according to claim 1, wherein:
the coating material covers the top face, the lateral face, and a corner portion between the top face and the lateral face, of the semiconductor chip mounted in the recess of the sintered member.

3. The semiconductor device according to claim 1, wherein:
porosity of the sintered member between the recess and the conductive pattern layer is lower than porosity of the frame in a cross-sectional view.

4. The semiconductor device according to claim 1, further comprising:
a protrusion projecting from the conductive pattern layer, at an outer side of the frame.

5. The semiconductor device according to claim 1, wherein:
the conductive pattern layer has a concave pit, and
the sintered member is disposed in the concave pit of the conductive pattern layer.

6. A semiconductor device manufacturing method, comprising:
preparing an insulated circuit board having a conductive pattern layer and a semiconductor chip having a top face, a bottom face, and a lateral face;
disposing a sintered member on the conductive pattern layer;
shaping the sintered member by
placing the semiconductor chip on the sintered member such that the bottom face opposes the sintered member, and
pressurizing, via the top face of the semiconductor chip, a region of the sintered member in contact with the bottom face of the semiconductor chip toward the conductive pattern layer,
so as to form a frame, to thereby form a recess in which the semiconductor chip is mounted, the frame shaping an outer edge of the recess and having a top end located at a higher level than the top face of the semiconductor chip; and
placing a coating material in the recess to cover the semiconductor chip.

7. The semiconductor device manufacturing method according to claim 6, wherein:
the placing of the coating material includes:
placing the coating material having fluidity on the top face of the semiconductor chip mounted in the recess, and
letting the placed coating material flow and spread.

8. The semiconductor device manufacturing method according to claim 6, wherein:
the placing of the coating material includes covering, with the coating material, the top face, the lateral face, and a corner portion between the top face and the lateral face, of the semiconductor chip mounted in the recess.

9. The semiconductor device manufacturing method according to claim 6, wherein:
the shaping of the sintered member includes heating the sintered member after pressurizing the sintered member.

10. The semiconductor device manufacturing method according to claim 6, wherein:
the shaping of the sintered member includes heating the sintered member while pressurizing the sintered member.

11. The semiconductor device manufacturing method according to claim 6, wherein:
the shaping of the sintered member uses a jig having
a plate portion,
a first surrounding portion provided on a first surface of the plate portion and projecting at a first height from the first surface, and
a second surrounding portion provided on the first surface of the plate portion and on an outer side of the first surrounding portion, and projecting, from the first surface, at a second height which is higher than the first height, and the shaping of the sintered member includes:
holding, on an inner side of the first surrounding portion, the semiconductor chip with the top face opposing the first surface,
forming the recess by causing the second surrounding portion of the jig with the semiconductor chip held therein to abut on the conductive pattern layer with the sintered member disposed thereon, to thereby pressurize the sintered member toward the conductive pattern layer, and, simultaneously forming the frame by extruding the sintered member into space between the first surrounding portion and the second surrounding portion, and
separating the jig from the semiconductor chip, the sintered member, and the conductive pattern layer.

12. The semiconductor device manufacturing method according to claim 11, wherein:
the jig is softer than the semiconductor chip.

13. The semiconductor device manufacturing method according to claim 11, wherein:
the jig has a layer softer than the semiconductor chip, on the first surface of the plate portion, at least in a region surrounded by the first surrounding portion.
